(19) United States
(12) Patent Application Publication
(10) Pub. No.: US 2013/0074897 A1
(43) Pub. Date: Mar. 28, 2013

(54) THERMOELECTRIC MODULE AND MANUFACTURING METHOD FOR THERMOELECTRIC MODULE

(71) Applicants: Ju Hwan YANG, Gyeonggi-do (KR); Dong Hyeok Choi, Gyeonggi-do (KR); Sung Ho Lee, Gyeonggi-do (KR)

(72) Inventors: Ju Hwan YANG, Gyeonggi-do (KR); Dong Hyeok Choi, Gyeonggi-do (KR); Sung Ho Lee, Gyeonggi-do (KR)

(73) Assignee: Samsung Electro-Mechanics Co., Ltd.

(21) Appl. No.: 13/620,898

(22) Filed: Sep. 15, 2012

(30) Foreign Application Priority Data
Sep. 27, 2011 (KR) 10-2011-0097813

(51) Int. Cl. H01L 35/28; H01L 35/34

(52) U.S. Cl. 136/200; 136/201

(57) ABSTRACT

The present invention is related to a thermoelectric module and a method for manufacturing the same. The thermoelectric module includes a substrate, a bottom electrode and a thermoelectric semiconductor. The thermoelectric module further includes an insulating layer integrally formed on a whole exposed surface of the bottom electrode, a portion of exposed surface of the thermoelectric semiconductor and a portion of exposed surface of the substrate; a contact hole provided in the insulating layer to expose a portion of a top surface of the thermoelectric semiconductor; and a top electrode to electrically connect at least two thermoelectric semiconductors by being formed on a surface of at least two thermoelectric semiconductors exposed by the contact hole and a portion of a top surface of the insulating layer.

### CROSS-REFERENCE TO RELATED APPLICATIONS

Claim and incorporate by reference domestic priority application and foreign priority application as follows:

“CROSS REFERENCE TO RELATED APPLICATION

This application claims the benefit under 35 U.S.C. Section 119 of Korean Patent Application Serial No. 10-2011-0097813, entitled filed Sep. 27, 2011, which is hereby incorporated by reference in its entirety into this application.”

### BACKGROUND OF THE INVENTION

1. Field of the Invention

The present invention relates to a thermoelectric module and a manufacturing method for a thermoelectric module.

2. Description of the Related Art

Due to the rapid increment in use of fossil energy, there have caused critical problems such as climate change and energy depletion according to global warming.

Recently, there have world-widely been many studies on a renewal energy development and a thermoelectric device development program in order to solve such problems.

On the other hand, since all apparatus and electronic devices cannot overcome the limitation of Carnot cycle thermodynamically, most of the inputted energy is discarded unnecessarily. Accordingly, if the discarded thermal energy can apply to a new application to use again, it will be a good methodology to overcome the crisis.

The thermoelectric effect means a reversible direct energy conversion between heat and electric, it is classified into a Peltier effect to be applied to a cooling field by using a temperature difference between both ends formed by the current applied from outside as an effect to be generated by the movement of the electrons and holes inside of a material and a Seebeck effect to be applied to a power generation field by using an electromotive force generated from a temperature difference between both ends of the material.

The heating value has been increased according to a miniaturization, a high power, a high integration, a slimness of electronic devices together with the development of IT industries; the generated heat acts as a major factor to deteriorate erroneous operation and efficiency of the electronic devices; there is continuously tried to apply the cooling function of the thermoelectric device in order to solve such problems; and also, it will be expected to further increase considering on the non-noise, rapid cooling speed, local cooling and environmentally friendly characteristics as the advantages of the thermoelectric device.

And also, there have been world widely implemented many efforts to regenerate electric energy using many waste heat discarded from an automobile, a waste incineration plant, a still mill, a power plant, a geothermal heat, an electronic device, a body temperature or the like in the electric generation field. More specifically, since the thermoelectric generation is a bulk generation and is capable of being integrated with other generations, future application possibilities are very large.

And also, since contaminated materials are not discharged in the process to generate electric energy, it will be expected that the spread speed of the thermoelectric generation is accelerated due to the conformity with the environmentally friendly characteristics.

However, since the commercialization of thermoelectric cooling and generation is not becoming more common world widely, the studies thereof are developed in the public research institutes and small size laboratories in the universities.

But, since there have been studied for the thermoelectric devices and modules in order to overcome problems due to the sharp rise of resource cost related to the recent energy, the future market may be large considering on the application possibility and advantage thereof.

With keeping pace with such situations, in order to maximize the applicability of the thermoelectric device, in the present invention, the optimum design is proposed to maximize the efficiencies of thermoelectric devices and modules.

A conventional thermoelectric device can be classified into a module part composed of an electrode and a substrate and a power supplying unit to supply a DC power to such modules. FIG. 1 is perspective view schematically showing a structure of a conventional thermoelectric module.

Referring to FIG. 1, the thermoelectric element uses conventional N-type and P-type semiconductors, arranges the N-type and P-type semiconductors consisting a plurality of pairs on a plane, and the thermoelectric module can be constructed by connecting them using an metal electrode in series again.

As shown in FIG. 1, the conventional thermoelectric module is basically constructed by including a thermoelectric device, metal electrodes and a ceramic substrate, and it is referred to as a single module.

Meanwhile, the conventional thermoelectric modules have a thermoelectric device relatively thick in thickness, in this result, a transfer path of heat from a heat absorbing part to a heat discharging part becomes small; there is a limitation to improve a heat discharging performance or a heating performance.

Accordingly, there is increased a need for a thermoelectric module implemented with a thin type.

On the other hand, in a patent reference 1, there is disclosed a thermoelectric module provided with an insulating layer formed by a screen printing method between a substrate and electrodes.

Including the technology disclosed in the patent reference 1, in case when a thin type thermoelectric module is implemented by using the conventional technology, since the formation of the thermoelectric semiconductor and the connection between the top and bottom electrodes are difficult and the distance between the top and bottom electrodes becomes narrow, there is a problem to secure an insulation thereof.

And also, in electrically connecting a plurality of thermoelectric semiconductors in the conventional method, the electrodes are arranged in zigzag, in this result, although in case when the number of thermoelectric semiconductors is several to dozens, the power is only applied by forming a negative terminal and a positive terminal by only one.

However, in this case, if the driving voltage is V1 to drive each of the thermoelectric semiconductors and the number of thermoelectric semiconductors consisting the thermoelectric module is N, there is a limitation to drive the thermoelectric module only when the power, i.e., total N×V1, must apply between the negative terminal and the positive terminal.

### PRIOR ART TECHNICAL REFERENCE

### Patent Reference

Patent reference 1: KR published patent document No. 10-2010-0116747

### SUMMARY OF THE INVENTION

The present invention has been invented in order to overcome the above-described problems and it is, therefore, an object of the present invention to provide a thermoelectric module capable of being implemented with a thin film and a manufacturing method for the same.

And also, it is another object of the present invention to provide a thermoelectric module capable of driving at a low voltage and a method for manufacturing the same.

In accordance with one aspect of the present invention to achieve the object, there is provided a thermoelectric module provided with a substrate, a bottom electrode and a thermoelectric semiconductor including: an insulating layer integrally formed on a whole exposed surface of the bottom electrode, a portion of exposed surface of the thermoelectric semiconductor and a portion of exposed surface of the substrate; a contact hole provided in the insulating layer to expose a portion of a top surface of the thermoelectric semiconductor; and a top electrode to electrically connect at least two thermoelectric semiconductors by being formed on a surface of at least two thermoelectric semiconductors exposed by the contact hole and a portion of a top surface of the insulating layer.

At this time, the thermoelectric semiconductor is formed on the bottom electrode with a thickness ranging from 1 μm to 50 μm.

And also, a thickness of the thermoelectric semiconductor is determined in a range of 0.1 to 1 times of a horizontal cross-section.

And also, thermoelectric semiconductor is formed on the bottom electrode with a thickness ranging from 1 μm to 50 μm and a thickness of the thermoelectric semiconductor is determined in a range of 0.1 to 1 times of a horizontal cross-section.

And also, the thermoelectric module further includes: an anisotropic conductive film, wherein one surface of the anisotropic conductive film is contact with a surface of at least one thermoelectric semiconductor exposed by the contact hole.

At this time, the thermoelectric module further includes: a flexible circuit board provided with an electrode pattern which is contact with the other surface of the anisotropic conductive film.

On the other hand, the thermoelectric semiconductor in accordance with the embodiment of the present invention includes a P-type thermoelectric semiconductor and an N-type thermoelectric semiconductor, the thermoelectric semiconductor alternatively positions a P-type thermoelectric semiconductor and an N-type thermoelectric semiconductor in a direction of an X-axis, the P-type thermoelectric semiconductor is positioned at the first place and the N-type thermoelectric semiconductor is positioned at the last place, the bottom electrodes are arranged in such a way that the thermoelectric semiconductors are electrically connected by two in the X-axis in series, and a first arrangement unit, which is made of an arrangement of the bottom electrodes and the thermoelectric semiconductors in the direction of the X-axis, becomes parallel to the X-axis and is repeatedly arranged in a direction of a Y-axis.

At this time, the top electrode electrically and serially connects two thermoelectric semiconductors continuously arranged in the direction of the X-axis.

And also, the top electrode electrically and serially connects two thermoelectric semiconductors continuously arranged in the direction of the X-axis for the remaining thermoelectric semiconductor except for the P-type thermoelectric semiconductor positioned at one end of the first arrangement unit and the N-type thermoelectric semiconductor positioned at the other end of the first arrangement unit.

And also, in the thermoelectric semiconductor, an anisotropic conductive film is further included in such a way that one surface thereof is contact with a surface of the thermoelectric semiconductor through contact holes formed in top surfaces of the P-type thermoelectric semiconductor positioned at the one end of the first arrangement unit and the N-type thermoelectric semiconductor positioned at the other end of the first arrangement unit.

At this time, the thermoelectric module further includes: a flexible circuit board on which an electrode pattern being contact with another surface of the anisotropic conductive film is formed.

And also, a thickness of the bottom electrode or the top electrode is ranging from 1 μm to 5 μm, and a top surface of the insulating layer is formed at a position separated below 102 μm in a vertical direction with reference to the top surface of the thermoelectric semiconductor.

In accordance with another aspect of the present invention to achieve the object, there is provided a method for manufacturing a thermoelectric module including: forming a bottom electrode on a substrate; forming a thermoelectric semiconductor on the bottom electrode; forming an insulating layer on the substrate, the bottom electrode and the thermoelectric semiconductor; forming a contact hole to expose a top surface of the thermoelectric semiconductor; and forming a top electrode to electrically connect at least two thermoelectric semiconductors by being contact with surfaces of at least two thermoelectric semiconductors exposed by the contact hole and a portion of the top surface of the insulating layer.

At this time, forming a thermoelectric semiconductor is to form the thermoelectric semiconductor having a thickness ranging from 10 μm to 50 μm by printing a paste including a volatile resin and a thermoelectric semiconductor material in the bottom electrode.

And also, forming a thermoelectric semiconductor is to form the thermoelectric semiconductor having a thickness ranging from 10 μm to 50 μm by depositing a thermoelectric semiconductor material on the bottom electrode using a sputtering or an E-beam method.

And also, the thermoelectric semiconductor is formed on the bottom electrode at a thickness of 1 μm to 5 μm and a thickness thereof is determined within a range of 0.1 to 1 times of a horizontal cross-section.

And also, forming an insulating layer on the substrate, the bottom electrode and the thermoelectric semiconductor is to attach an insulating film on the substrate, the bottom electrode and the thermoelectric semiconductor in vacuum condition.

And also, forming an insulating layer on the substrate, the bottom electrode and the thermoelectric semiconductor is to form an oxide layer on the substrate, the bottom electrode and the thermoelectric semiconductor.

And also, forming a contact hole is to etch a portion of the top surface of the thermoelectric semiconductor in the insulating layer.

And also, the method for manufacturing a thermoelectric module, after forming a contact hole, further includes: contacting one surface of an anisotropic conductive film to a surface of at least one thermoelectric semiconductor exposed by the contact hole.

And also, the method for manufacturing a thermoelectric module, after forming a contact hole, further includes: contacting one surface of an anisotropic conductive film to a surface of at least one thermoelectric semiconductor exposed by the contact hole and contacting a flexible circuit board provided with an electrode pattern to the other surface of the anisotropic conductive film.

And also, a thickness of the bottom electrode or the top electrode is ranged from 1 μm to 5 μm and the top surface of the insulating layer is formed at a position separated below 10 μm in a vertical direction with reference to the top surface of the thermoelectric semiconductor.

In accordance with still another aspect of the present invention to achieve the object, there is provided a method for manufacturing a thermoelectric module including: forming a bottom electrode on a substrate and forming a P-type thermoelectric semiconductor and an N-type thermoelectric semiconductor; forming an insulating layer on the substrate, the bottom electrode, the P-type thermoelectric semiconductor and the N-type thermoelectric semiconductor; forming contact holes to expose top surfaces of the P-type thermoelectric semiconductor and the N-type thermoelectric semiconductor; and forming top electrodes to electrically connect the P-type thermoelectric semiconductor and the N-type thermoelectric semiconductor by being contact with surfaces of the P-type thermoelectric semiconductor and the N-type thermoelectric semiconductor exposed by the contact holes and a portion of the top surface of the insulating layer, wherein the thermoelectric semiconductor alternatively positions the P-type thermoelectric semiconductor and the N-type thermoelectric semiconductor in a direction of an X-axis, the P-type thermoelectric semiconductor is positioned at the first place and the N-type thermoelectric semiconductor is positioned at the last place; the bottom electrodes are arranged in such a way that the thermoelectric semiconductors are electrically connected by two in the X-axis in series; and a first arrangement unit, which is made of an arrangement of the bottom electrodes and the thermoelectric semiconductors in the direction of the X-axis, becomes parallel to the X-axis and is repeatedly arranged in a direction of a Y-axis.

And also, forming top electrodes is to form the top electrode so as to electrically and serially connect two thermoelectric semiconductors continuously arranged in the direction of the X-axis.

And also, forming top electrodes is to form the top electrode so as to electrically and serially connect two thermoelectric semiconductors continuously arranged in the direction of the X-axis for the remaining thermoelectric semiconductor except for the P-type thermoelectric semiconductor positioned at one end of the first arrangement unit and the N-type thermoelectric semiconductor positioned at the other end of the first arrangement unit.

And also, the method for manufacturing a thermoelectric module, after forming a contact hole, further includes: contacting one surface of the anisotropic conductive film to a surface of the thermoelectric semiconductor exposed by the contact holes formed in top surfaces of the P-type thermoelectric semiconductor positioned at the one end of the first arrangement unit and the N-type thermoelectric semiconductor positioned at the other end of the first arrangement unit.

And also, the method for manufacturing a thermoelectric module, after forming a contact hole, further includes: contacting one surface of the anisotropic conductive film to a surface of the thermoelectric semiconductor exposed by the contact holes formed in top surfaces of the P-type thermoelectric semiconductor positioned at the one end of the first arrangement unit and the N-type thermoelectric semiconductor positioned at the other end of the first arrangement unit and contacting a flexible circuit board on which an electrode pattern to the other surface of the anisotropic conductive film.

And also, a thickness of the bottom electrode or the top electrode is ranged from 1 μm to 5 μm and the top surface of the insulating layer is formed at a position separated below 10 μm in a vertical direction with reference to the top surface of the thermoelectric semiconductor.

In accordance with still another aspect of the present invention to achieve the object, there is provided a method for manufacturing a thermoelectric module including: forming a bottom electrode on a substrate; forming thermoelectric semiconductors on the bottom electrode; forming release parts within top surfaces of the thermoelectric semiconductors; forming an insulating layer on the substrate, the bottom electrode and the release parts; forming contact holes to expose the top surface of the thermoelectric semiconductors by removing the release part; and forming top electrodes to electrically connect at least two thermoelectric semiconductors by being contact with surfaces of at least two thermoelectric semiconductors and a portion of the top surface of the insulating layer.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a perspective view schematically showing a structure of a conventional thermoelectric module;

FIG. 2 is a perspective view schematically showing a thermoelectric module in accordance with one embodiment of the present invention;

FIG. 3 is a vertical cross-sectional view schematically a thermoelectric module in accordance with another embodiment of the present invention;

FIG. 4 is a vertical cross-sectional view showing an application example of the thermoelectric module in accordance with one embodiment of the present invention;

FIG. 5A to 5G are process perspective views showing a manufacturing method for the thermoelectric module in accordance with one embodiment of the present invention; and

FIG. 6A to 6G are process perspective views showing a manufacturing method for the thermoelectric module in accordance with another embodiment of the present invention.

### DETAILED DESCRIPTION OF THE PREFERABLE EMBODIMENTS

Hereinafter, embodiments of the present invention will be described in detail with reference to the accompanying drawings. The following embodiments are provided as examples to fully convey the spirit of the invention to those skilled in the art.

Therefore, the present invention should not be construed as limited to the embodiments set forth herein and may be embodied in different forms. And, the size and the thickness of an apparatus may be overdrawn in the drawings for the convenience of explanation. The same components are represented by the same reference numerals hereinafter.

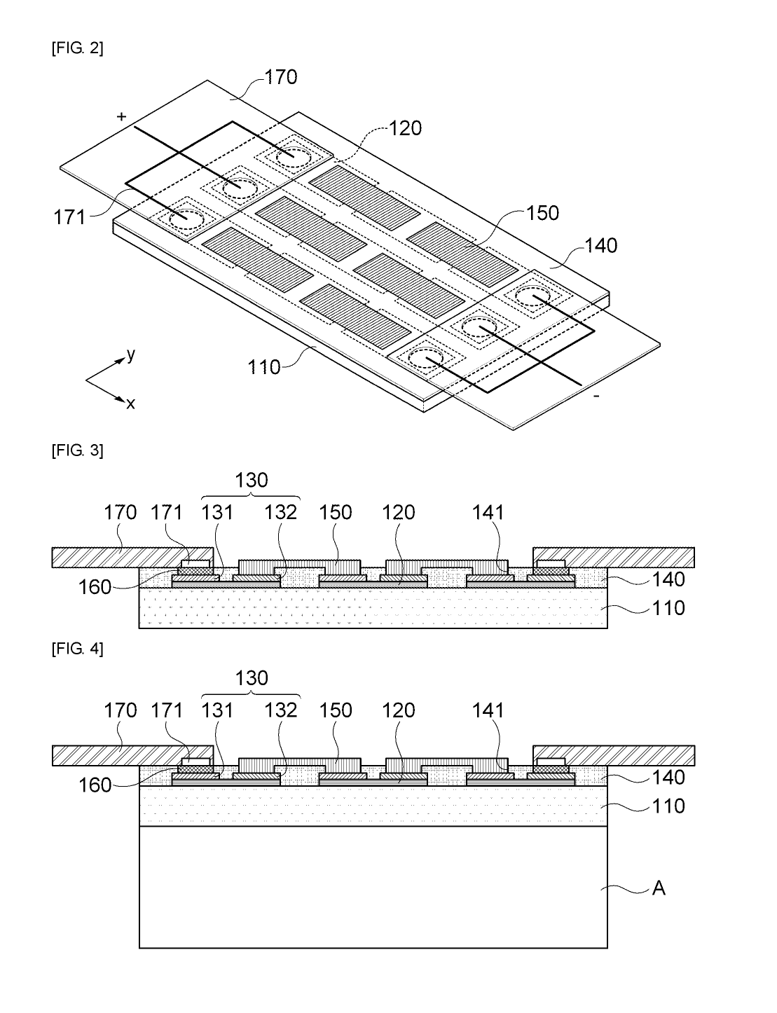

FIG. 2 is a perspective view schematically showing a thermoelectric module in accordance with one embodiment of the present invention and FIG. 3 is a vertical cross-sectional view schematically a thermoelectric module in accordance with another embodiment of the present invention.

Referring to FIG. 2 and FIG. 3, the thermoelectric module 100 in accordance with the present invention can include a substrate 110, a bottom electrode 120, thermoelectric semiconductors 130 and a top electrode.

As the substrate 110 plays a role of supporting the thermoelectric module and performs a heat absorbing or a heat discharging function by being in contact with a heat discharging or a heat absorbing object, it can be made of a material such as alumina Al₂O₃ used in a conventional thermoelectric module.

As the bottom electrode 120 plays roles of supplying power to the thermoelectric semiconductors 130 and electrically connecting the thermoelectric semiconductors 130 by being formed on the substrate 110 at various methods, it can be realized by a screen printing method.

At this time, since the thermoelectric module in accordance with one embodiment of the present invention is characterized in that it is implemented in a shape of thin film, it is advantageous that the bottom electrode 120 is also implemented in a shape of thin film in order to meet such features of the present invention, and it is preferable to be deposited by a sputtering or an E-beam method in order to this.

And also, it is preferable that a thickness of the bottom electrode 120 is ranged from 1 μm to 5 μm.

The thermoelectric semiconductor 130 can play roles of moving heat by electric energy or generating the electric energy by a temperature difference between a top and a bottom by being formed on the bottom electrode 120.

At this time, the thermoelectric semiconductor 130 includes a P-type thermoelectric semiconductor 131 and an N-type thermoelectric semiconductor 132, and it is preferable that the thickness thereof is ranged from 1 μm to 50 μm in order to implement the thin film thermoelectric module.

On the other hand, the thermoelectric semiconductor 130 can be implemented by a method to coat a paste obtained by mixing a resin having a volatile characteristics according to a heat treatment with a material of the thermoelectric semiconductor 130 with a screen printing method.

And also, it is preferable that the thermoelectric semiconductor 130 having a thickness below 5 μm is implemented on the bottom electrode 120 with a sputtering or an E-beam method.

At this time, a thickness of the thermoelectric semiconductor 130 in comparison with a horizontal cross-section, i.e., thickness/cross-section, may be within a range of 0.1 to 1. If exceeding the range, the reduction of cooling effect is induced due to the decrease of heat conductivity, and if being below the range, the cooling efficiency is reduced by occurring a direct heat transfer between the top electrode 150 and the bottom electrode 120.

The insulating layer 140 plays roles of preventing a short phenomenon and protecting the thermoelectric semiconductors 130 or the like by being formed on the substrate 110, the bottom electrode 120 and the thermoelectric semiconductors 130.

And also, in order for thinning the thermoelectric module, it can be implemented by attaching the insulating film having a thickness ranging from 30 μm to 60 μm using a vacuum adhesion method.

At this time, the insulating layer 140 can be implemented by a method to coat an epoxy molding compound which has excellent forming and mechanical characteristics and is a relatively cheap material cost.

And also, it can be implemented by an oxide layer forming method through a plasma enhanced CVD method, and it is advantageous for thinning the thermoelectric module when the insulating layer 140 having a thickness of 5 μm is formed by using this method.

Meanwhile, the insulating layer 140 can be formed on the exposed whole top surfaces of the substrate 110, the bottom electrode 120 and the thermoelectric semiconductors 130 in a lump. At this time, since the top surface of the thermoelectric semiconductors 130 is electrically connected to the top electrode 150, it is preferable that the contact hole 141 is formed in the insulating layer 140 provided in the top surface of the thermoelectric semiconductors 130.

The contact hole 141 can be formed by a method to remove a region of the insulating layer 140 necessary for an exposure with an etching method after a batch forming of the insulating layer 140.

And also, before forming the insulating layer 140, a release part 142 is formed at a portion where the contact hole 141 is formed, and after finishing the formation of the insulating layer 140, by removing the portion of the release part 142, the contact hole 141 can be formed.

The contact hole 141 can be formed on the whole or a portion of the thermoelectric semiconductor 130, and it is preferable that the contact hole 141 is formed in a central region at the top surface of the thermoelectric semiconductor 130 in order to prevent the short phenomenon between the top electrode 150 and the bottom electrode 120.

The top electrode 150 plays a role of electrically connecting the thermoelectric semiconductors 130 by being formed on the surface of the insulating layer 140 and the contact hole 141.

At this time, it is preferable that a thickness of the top electrode 150 is ranged from 1 μm to 5 μm in order for thinning the thermoelectric module, and it can be implemented by applying a deposition method such as a screen printing method, a sputtering and an E-beam or the like similar to the implementation method of the above-described bottom electrode 120.

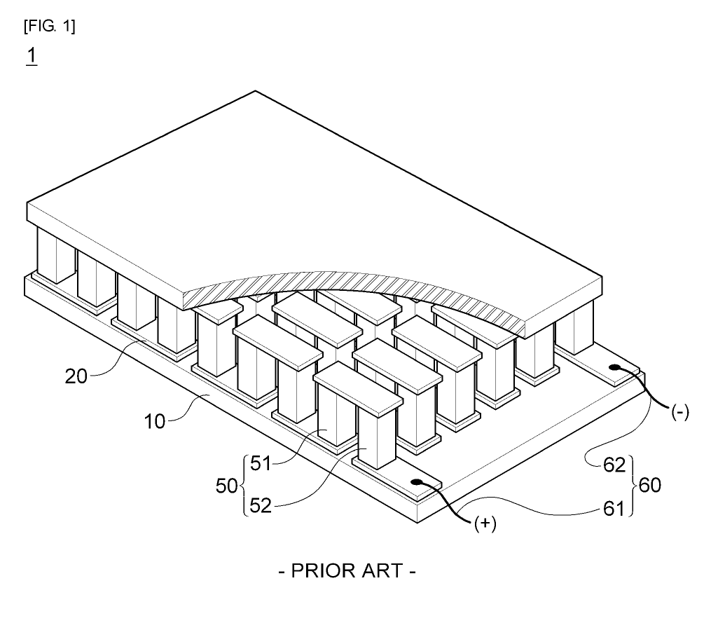

On the other hand, in the contact hole 141 of the thermoelectric semiconductor 130 positioned at both ends of the thermoelectric module, an anisotropic conductive film (ACF) 160 can be attached. In the conventional method, although a method to electrically connect a power line (referring to 60 of FIG. 1) and an electrode (20 of FIG. 1) using a method such as a soldering, considering on the thinning and the reliability of the power line connection part, it is preferable that the power is connected by using the anisotropic conductive film 160.

And also, in the top surface of the thermoelectric module in accordance with one embodiment of the present invention, the contact hole 141 is formed, in order to directly connect such contact hole 141 to an electrode pattern 171, it is preferable that the anisotropic conductive film 160 is applied for securing the conductivity due to a filler of the anisotropic conductive film 160.

That is, in the surface of the thermoelectric semiconductor 130, one surface of the anisotropic conductive film 160 is attached, and in the other surface of the anisotropic conductive film 160 the electrode pattern 171 is contacted, thereby transferring the power to the thermoelectric semiconductor 130 through the electrode pattern 171.

At this time, the electrode pattern 171 can be in contact with the anisotropic conductive film 160 under the condition that the flexible printed circuit board (FPCB) 170 is formed.

On the other hand, the thermoelectric semiconductor 130 includes a P-type thermoelectric semiconductor 131 and an N-type thermoelectric semiconductor 132.

A conventional thermoelectric module is formed by combining several to hundreds, the conventional thermoelectric module connects all of the thermoelectric semiconductors forming one thermoelectric module in series, it employs a shape to supply the power by connecting one “+” power terminal to one “−” power terminal to by providing a lead part on the electrodes positioned at one end and the other end among the serially connected thermoelectric semiconductors.

However, since the above-mentioned method the voltage to drive a number of thermoelectric semiconductors is applied through the “+” terminal and the “−” terminal, only when a relatively high voltage is applied, the heat discharging function or the heat absorbing function of the thermoelectric semiconductor 130 can be realized.

In order to solve such problems, the thermoelectric module in accordance with the present invention arranges a first arrangement unit formed of the thermoelectric semiconductor 130, the bottom electrode 120 and the top electrode 150 in parallel to be available for a low voltage driving; and, therefore, the thermoelectric module is proposed to apply the voltage to each of the first arrangement units, respectively.

Referring to FIG. 2 and FIG. 3, the P-type thermoelectric semiconductor 131 and the N-type thermoelectric semiconductor 132 are alternately positioned in a direction of X-axis, the P-type thermoelectric semiconductor 131 is positioned at first and the N-type thermoelectric semiconductor is positioned at last, the bottom electrode 120 is arranged to allow the thermoelectric semiconductors 130 to be electrically in series by two in the direction of X-axis, and the first arrangement unit formed of an arrangement of X-axis direction of the bottom electrode 120 and the thermoelectric semiconductors 130 is repeated in the direction of Y-axis with being in parallel with the X-axis.

At this time, the top electrode 150 electrically connects two thermoelectric semiconductors 130 continuously arranged in the direction of X-axis in series, the remaining thermoelectric semiconductors 130 except for the P-type thermoelectric semiconductor placed at one end of the first arrangement unit and the N-type thermoelectric semiconductor 132 placed at the other end of the first arrangement unit are electrically connected in series.

And also, the surfaces of the thermoelectric semiconductors 130 are coupled to an anisotropic conductive film 160 through the contact holes 141 formed on the top surfaces of the P-type thermoelectric semiconductor 131 placed at the one end of the first arrangement unit and the N-type thermoelectric 132 placed at the other end of the first arrangement unit.

And also, by joining the electrode pattern 171 being in contact with the other surface of the anisotropic conductive film 160, the thermoelectric module can be driven by a low voltage in comparison with a prior art by being capable of applying the voltage to drive only the thermoelectric semiconductors 130 forming each of the first arrangement units.

FIG. 4 is a vertical cross-sectional view showing an application example of the thermoelectric module in accordance with one embodiment of the present invention.

Referring to FIG. 4, since the thermoelectric module in accordance with one embodiment of the present invention can be implemented by a very thin thickness in comparison with the conventional thermoelectric module, it has an excellent heat discharging effect; and, in case when an electronic device is implemented by employing the thermoelectric module in accordance with one embodiment of the present invention as a heat discharging means, it can realize a slimness on the whole.

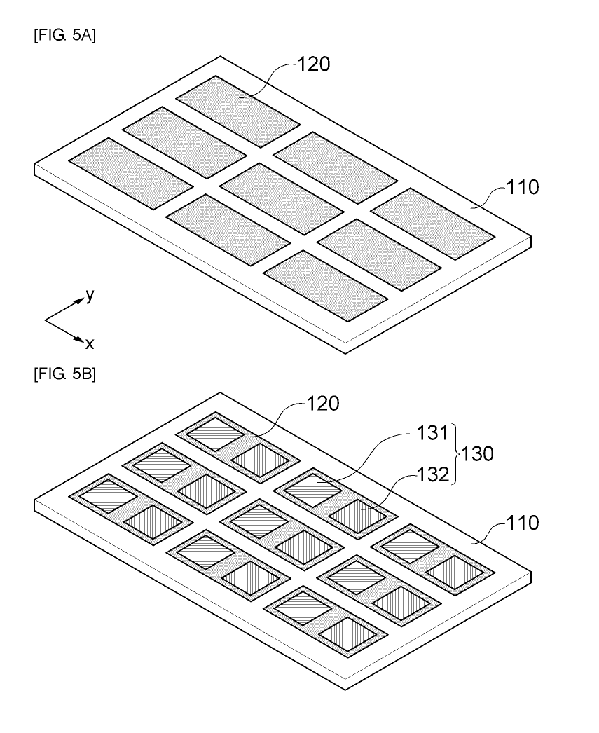

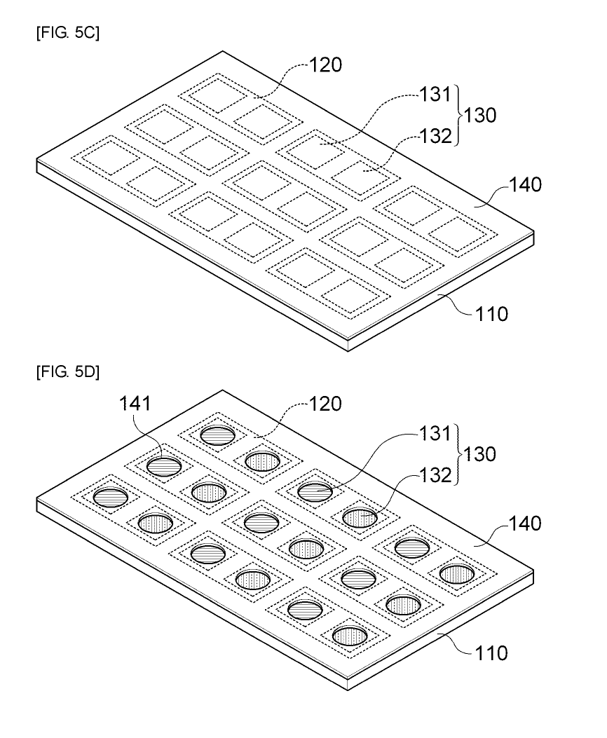

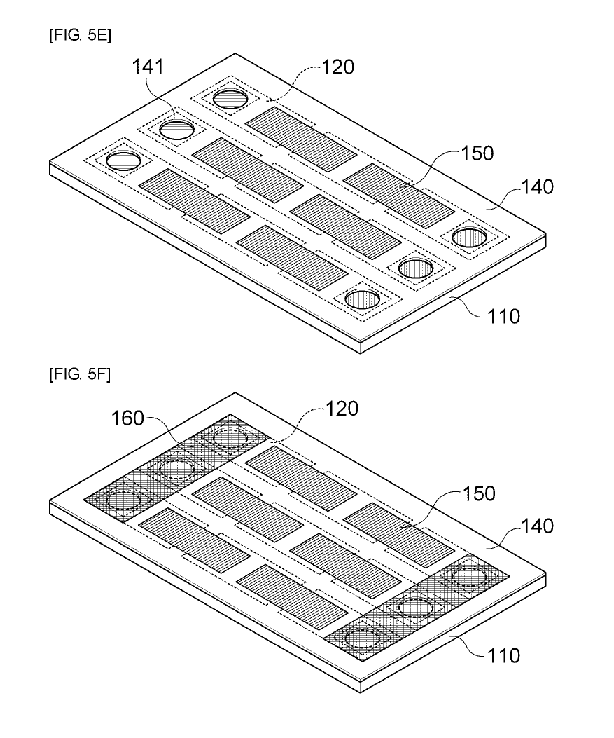

FIG. 5A to 5G are process perspective views showing a manufacturing method for the thermoelectric module in accordance with one embodiment of the present invention.

Hereinafter, a manufacturing method for the thermoelectric module in accordance with another embodiment of the present invention will be explained in detail with reference to FIG. 5A to 5G.

At first, as shown in FIG. 5A, a bottom electrode 120 is formed on a substrate 110.

At this time, in order for thinning the thermoelectric module, it is preferable that the bottom electrode 120 is implemented at a thickness ranging from 1 μm to 5 μm by being deposited with a sputtering or an E-beam method.

Thereafter, as shown in FIG. 5B, the thermoelectric semiconductor 130 is formed on the bottom electrode 120.

The thermoelectric semiconductor 130 can be implemented by a method to coat a paste mixed with the resin having volatile characteristics according to a heat treatment and a material of the thermoelectric semiconductor 130 on the bottom electrode 120 using a screen printing method.

And also, the thermoelectric semiconductor 130 having a thickness below 5 μm may be implemented on the bottom electrode 120 by using a sputtering or an E-beam method.

At this time, a comparison between a horizontal cross-section and a thickness, i.e., thickness/cross-section, of the thermoelectric semiconductor 130 can be in the range of 0.1 to 1. If exceeding this range, the decrease of cooling efficiency is induced due to the reduction of heat conductivity; and, if being below this range, the decrease of cooling efficiency is also induced since a heat transfer is directly performed between the top electrode 150 and the bottom electrode 120.

And then, as shown in FIG. 5C, an insulating layer 140 is formed on the substrate 110, the bottom electrode 120 and the thermoelectric semiconductor 130.

At this time, the insulating layer 140 can be implemented by attaching an insulating film having a thickness of 30 μm to 60 μm with a vacuum adhesion method.

And also, the insulating layer 140 having a thickness of 5 μm can be implemented by using an oxide film forming method through a plasma enhanced chemical vapor deposition (PECVD) method.

Thereafter, as shown in FIG. 5D, a contact hole 141 is formed to expose a top surface of the thermoelectric semiconductor 130.

The contact hole 141 can be formed by a method to remove the insulating layer 140 of a region need to be exposed by an etching method after a batch formation of the insulating layer 140.

Thereafter, as shown in FIG. 5E, the top electrode 150 is formed.

At this time, it is preferable that the thickness of the top electrode 150 is formed within a ranging from 1 μm to 5 μm in order for a thinning of the thermoelectric module, and it can be implemented by using a deposition method such as a screen printing method, a sputtering or an E-beam similar to the implementation method of the above-described bottom electrode 120.

Thereafter, as shown in FIG. 5F and FIG. 5G, one surface of the anisotropic conductive film 160 is in contact with a surface of at least one thermoelectric semiconductor 130 exposed by the contact hoe 141, and the other surface of the anisotropic film 160 is in contact with a flexible circuit board 110 provided with an electrode pattern 171.

At this time, as described above, the first arrangement unit composed of the thermoelectric semiconductor 130, a top electrode and a bottom electrode is arranged in parallel, and the electrode pattern 171, which is in contact with the other surface of the anisotropic conductive film 160, can be coupled in order to apply the voltage to each of the first arrangement units, respectively.

Accordingly, the thermoelectric module can be driven at a low voltage in comparison with a prior art so as to apply the voltage capable of driving only the thermoelectric semiconductors 130 forming each of the first arrangement units.

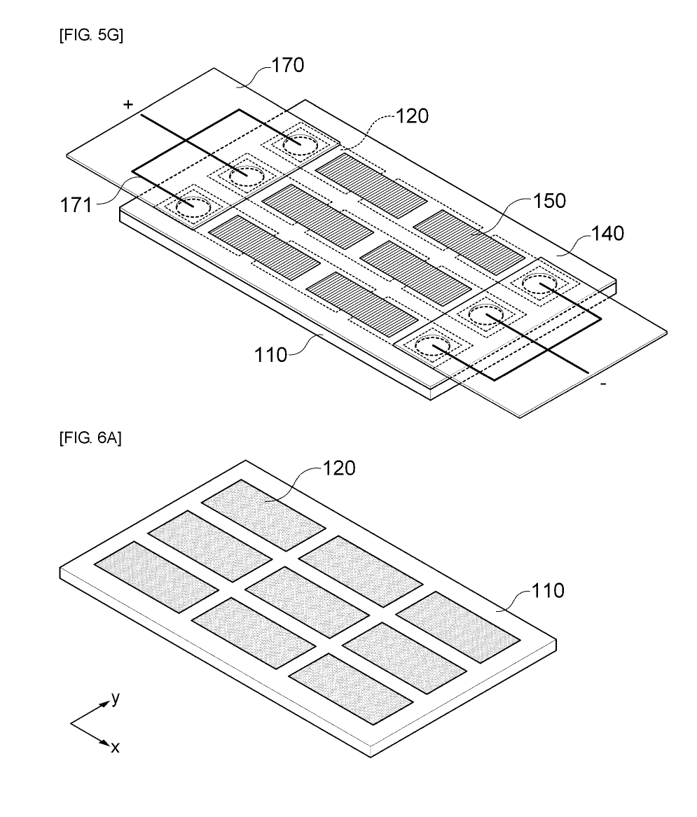

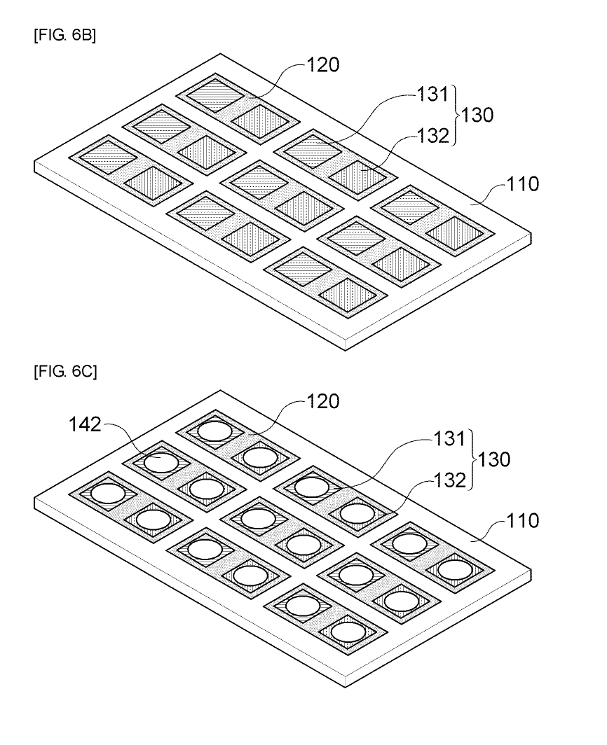

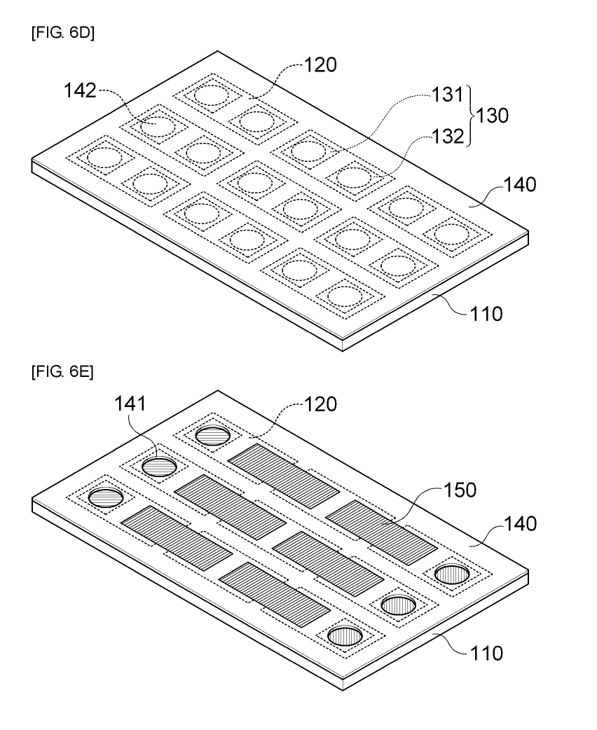

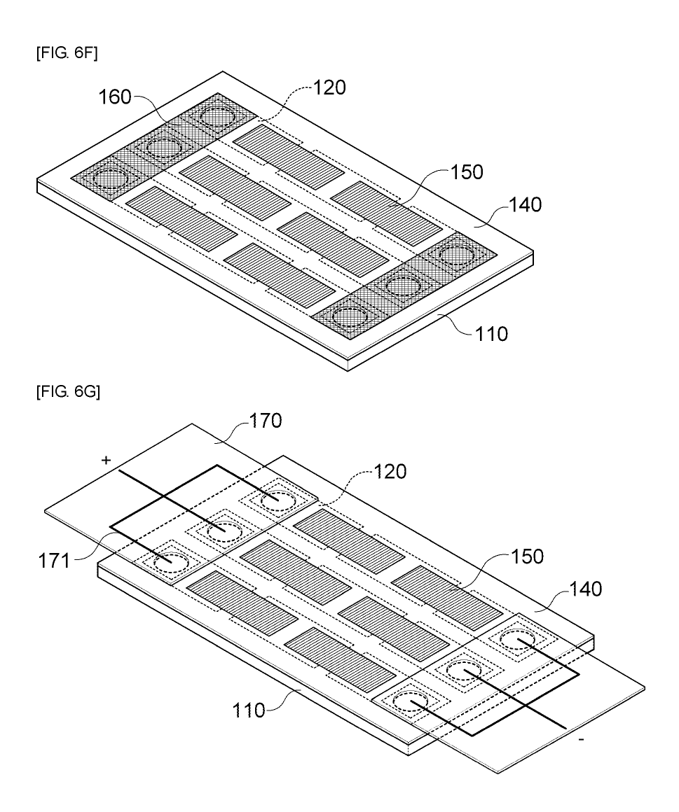

FIG. 6A to 6G are process perspective views showing a manufacturing method for the thermoelectric module in accordance with another embodiment of the present invention.

Referring to FIG. 6A to 6G, as shown in FIG. 6C, a release part 142 is formed on a top surface of the thermoelectric semiconductor 130, and as shown in FIG. 6D, after forming the insulating layer 140, the contact hole 141 can be implemented by removing the release part 142, as shown in FIG. 6E.

The same explanations for the other processes will be omitted since they are similar to the above-described explanations with reference to FIG. 5A to 5G.

Since the thermoelectric module in accordance with one embodiment of the present invention constructed as described above can be implemented with a thin film, it improves the efficiency of heat discharging as well as it provides a useful effect for a miniaturization of an electronic device including the same when it is mounted together with a chip or the like at the same time.

And also, since the thermoelectric module in accordance with one embodiment of the present invention can further efficiently implement the connection part of the thermoelectric semiconductor and the power terminals, the reliability of the connection part can be improved.

And also, as there is provided the arrangement unit in a shape of parallel to apply the same voltage to one side of one thermoelectric model, respectively, there is provided a useful effect to drive a plurality of thermoelectric semiconductors at a low voltage.

This invention may be embodied in different forms and should not be construed as limited to the embodiments set forth herein. Rather, these embodiments are provided so that this disclosure will be thorough and complete, and will fully convey the scope of the invention to those skilled in the art. As described above, although the preferable embodiments of the present invention have been shown and described, it will be appreciated by those skilled in the art that substitutions, modifications and variations may be made in these embodiments without departing from the principles and spirit of the general inventive concept, the scope of which is defined in the appended claims and their equivalents.

What is claimed is:

1. A thermoelectric module provided with a substrate, a bottom electrode and a thermoelectric semiconductor comprising:
an insulating layer integrally formed on a whole exposed surface of the bottom electrode, a portion of exposed surface of the thermoelectric semiconductor and a portion of exposed surface of the substrate;
a contact hole provided in the insulating layer to expose a portion of a top surface of the thermoelectric semiconductor; and
a top electrode to electrically connect at least two thermoelectric semiconductors by being formed on a surface of at least two thermoelectric semiconductors exposed by the contact hole and a portion of a top surface of the insulating layer.

2. The thermoelectric module according to claim 1, wherein the thermoelectric semiconductor is formed on the bottom electrode with a thickness ranging from 1 μm to 50 μm.

3. The thermoelectric module according to claim 1, wherein a thickness of the thermoelectric semiconductor is determined in a range of 0.1 to 1 times of a horizontal cross-section.

4. The thermoelectric module according to claim 1, wherein the thermoelectric semiconductor is formed on the bottom electrode with a thickness ranging from 1 μm to 50 μm and a thickness of the thermoelectric semiconductor is determined in a range of 0.1 to 1 times of a horizontal cross-section.

5. The thermoelectric module according to claim 1, further comprising:
an anisotropic conductive film,
wherein one surface of the anisotropic conductive film is contact with a surface of at least one thermoelectric semiconductor exposed by the contact hole.

6. The thermoelectric module according to claim 5, further comprising:
a flexible circuit board provided with an electrode pattern which is contact with the other surface of the anisotropic conductive film.

7. The thermoelectric module according to claim 1, wherein the thermoelectric semiconductor includes a P-type thermoelectric semiconductor and an N-type thermoelectric semiconductor,
the thermoelectric semiconductor alternatively positions a P-type thermoelectric semiconductor and an N-type thermoelectric semiconductor in a direction of an X-axis, the P-type thermoelectric semiconductor is positioned at the first place and the N-type thermoelectric semiconductor is positioned at the last place,
the bottom electrodes are arranged in such a way that the thermoelectric semiconductors are electrically connected by two in the X-axis in series, and
a first arrangement unit, which is made of an arrangement of the bottom electrodes and the thermoelectric semiconductors in the direction of the X-axis, becomes parallel to the X-axis and is repeatedly arranged in a direction of a Y-axis.

8. The thermoelectric module according to claim 7, wherein the top electrode electrically and serially connects two thermoelectric semiconductors continuously arranged in the direction of the X-axis.

9. The thermoelectric module according to claim 7, wherein the top electrode electrically and serially connects two thermoelectric semiconductors continuously arranged in the direction of the X-axis for the remaining thermoelectric semiconductor except for the P-type thermoelectric semiconductor positioned at one end of the first arrangement unit and the N-type thermoelectric semiconductor positioned at the other end of the first arrangement unit.

10. The thermoelectric module according to claim 7, wherein in the thermoelectric semiconductor an anisotropic conductive film is further included in such a way that one surface thereof is contact with a surface of the thermoelectric semiconductor through contact holes formed in top surfaces of the P-type thermoelectric semiconductor positioned at the one end of the first arrangement unit and the N-type thermoelectric semiconductor positioned at the other end of the first arrangement unit.

11. The thermoelectric module according to claim 10, further comprising:
a flexible circuit board on which an electrode pattern being contact with another surface of the anisotropic conductive film is formed.

12. The thermoelectric module according to claim 1, wherein a thickness of the bottom electrode or the top electrode is ranging from 1 μm to 5 μm, and
a top surface of the insulating layer is formed at a position separated below 102 μm in a vertical direction with reference to the top surface of the thermoelectric semiconductor.

13. A method for manufacturing a thermoelectric module comprising:
forming a bottom electrode on a substrate;
forming a thermoelectric semiconductor on the bottom electrode;
forming an insulating layer on the substrate, the bottom electrode and the thermoelectric semiconductor;
forming a contact hole to expose a top surface of the thermoelectric semiconductor; and
forming a top electrode to electrically connect at least two thermoelectric semiconductors by being contact with surfaces of at least two thermoelectric semiconductors exposed by the contact hole and a portion of the top surface of the insulating layer.

14. The method for manufacturing a thermoelectric module according to claim 13, wherein forming a thermoelectric semiconductor is to form the thermoelectric semiconductor having a thickness ranging from 10 μm to 50 μm by printing a paste including a volatile resin and a thermoelectric semiconductor material in the bottom electrode.

15. The method for manufacturing a thermoelectric module according to claim 13, wherein forming a thermoelectric semiconductor is to form the thermoelectric semiconductor having a thickness ranging from 10 μm to 50 μm by depositing a thermoelectric semiconductor material on the bottom electrode using a sputtering or an E-beam method.

16. The method for manufacturing a thermoelectric module according to claim 13, wherein the thermoelectric semiconductor is formed on the bottom electrode at a thickness of 1 μm to 5 μm and a thickness thereof is determined within a range of 0.1 to 1 times of a horizontal cross-section.

17. The method for manufacturing a thermoelectric module according to claim 14, wherein forming an insulating layer on the substrate, the bottom electrode and the thermoelectric semiconductor is to attach an insulating film on the substrate, the bottom electrode and the thermoelectric semiconductor in vacuum condition.

18. The method for manufacturing a thermoelectric module according to claim 15, wherein forming an insulating layer on the substrate, the bottom electrode and the thermoelectric semiconductor is to form an oxide layer on the substrate, the bottom electrode and the thermoelectric semiconductor.

19. The method for manufacturing a thermoelectric module according to claim 13, wherein forming a contact hole is to etch a portion of the top surface of the thermoelectric semiconductor in the insulating layer.

20. The method for manufacturing a thermoelectric module according to claim 13, after forming a contact hole, further comprising:
contacting one surface of an anisotropic conductive film to a surface of at least one thermoelectric semiconductor exposed by the contact hole.

21. The method for manufacturing a thermoelectric module according to claim 13, after forming a contact hole, further comprising:
contacting one surface of an anisotropic conductive film to a surface of at least one thermoelectric semiconductor exposed by the contact hole and contacting a flexible circuit board provided with an electrode pattern to the other surface of the anisotropic conductive film.

22. The method for manufacturing a thermoelectric module according to claim 13, wherein a thickness of the bottom electrode or the top electrode is ranged from 1 μm to 5 μm and the top surface of the insulating layer is formed at a position separated below 10 μm in a vertical direction with reference to the top surface of the thermoelectric semiconductor.

23. A method for manufacturing a thermoelectric module comprising:
forming a bottom electrode on a substrate and forming a P-type thermoelectric semiconductor and an N-type thermoelectric semiconductor;
forming an insulating layer on the substrate, the bottom electrode, the P-type thermoelectric semiconductor and the N-type thermoelectric semiconductor;
forming contact holes to expose top surfaces of the P-type thermoelectric semiconductor and the N-type thermoelectric semiconductor; and
forming top electrodes to electrically connect the P-type thermoelectric semiconductor and the N-type thermoelectric semiconductor by being contact with surfaces of the P-type thermoelectric semiconductor and the N-type thermoelectric semiconductor exposed by the contact holes and a portion of the top surface of the insulating layer,
wherein the thermoelectric semiconductor alternatively positions the P-type thermoelectric semiconductor and the N-type thermoelectric semiconductor in a direction of an X-axis, the P-type thermoelectric semiconductor is positioned at the first place and the N-type thermoelectric semiconductor is positioned at the last place;
the bottom electrodes are arranged in such a way that the thermoelectric semiconductors are electrically connected by two in the X-axis in series; and
a first arrangement unit, which is made of an arrangement of the bottom electrodes and the thermoelectric semiconductors in the direction of the X-axis, becomes parallel to the X-axis and is repeatedly arranged in a direction of a Y-axis.

24. The method for manufacturing a thermoelectric module according to claim 23, wherein forming top electrodes is to form the top electrode so as to electrically and serially connect two thermoelectric semiconductors continuously arranged in the direction of the X-axis.

25. The method for manufacturing a thermoelectric module according to claim 23, wherein forming top electrodes is to form the top electrode so as to electrically and serially connect two thermoelectric semiconductors continuously arranged in the direction of the X-axis for the remaining thermoelectric semiconductor except for the P-type thermoelectric semiconductor positioned at one end of the first arrangement unit and the N-type thermoelectric semiconductor positioned at the other end of the first arrangement unit.

26. The method for manufacturing a thermoelectric module according to claim 13, after forming a contact hole, further comprising:
contacting one surface of the anisotropic conductive film to a surface of the thermoelectric semiconductor exposed by the contact holes formed in top surfaces of the P-type thermoelectric semiconductor positioned at the one end of the first arrangement unit and the N-type thermoelectric semiconductor positioned at the other end of the first arrangement unit.

27. The method for manufacturing a thermoelectric module according to claim 13, after forming a contact hole, further comprising:
contacting one surface of the anisotropic conductive film to a surface of the thermoelectric semiconductor exposed by the contact holes formed in top surfaces of the P-type thermoelectric semiconductor positioned at the one end of the first arrangement unit and the N-type thermoelectric semiconductor positioned at the other end of the first arrangement unit and contacting a flexible circuit board on which an electrode pattern to the other surface of the anisotropic conductive film.

28. The method for manufacturing a thermoelectric module according to claim 13, wherein a thickness of the bottom electrode or the top electrode is ranged from 1 μm to 5 μm and the top surface of the insulating layer is formed at a position separated below 10 μm in a vertical direction with reference to the top surface of the thermoelectric semiconductor.

29. A method for manufacturing a thermoelectric module comprising:
forming a bottom electrode on a substrate;
forming thermoelectric semiconductors on the bottom electrode;
forming release parts within top surfaces of the thermoelectric semiconductors;
forming an insulating layer on the substrate, the bottom electrode and the release parts;
forming contact holes to expose the top surface of the thermoelectric semiconductors by removing the release part; and
forming top electrodes to electrically connect at least two thermoelectric semiconductors by being contact with surfaces of at least two thermoelectric semiconductors and a portion of the top surface of the insulating layer.
